(19) United States
(12) Patent Application Publication
(10) Pub. No.: US 2015/0162470 A1
(43) Pub. Date: Jun. 11, 2015

(54) STRUCTURE FOR FORMING SOLAR CELLS

(71) Applicants: Guy Chichignoud, Grenoble (FR); Elisabeth Blanquet, Claix (FR); Isabelle Gelard, Saint Martin D''Heres (FR); Carmen Jimenez, Grenoble (FR); Eirini Sarigiannidou, Saint Egreve (FR); Kader Zaidat, Saint Martin D''Heres (FR); Francois Weiss, Montbonnot (FR); Michel Pons, La Tronche (FR)

(72) Inventors: Guy Chichignoud, Grenoble (FR); Elisabeth Blanquet, Claix (FR); Isabelle Gelard, Saint Martin D''Heres (FR); Carmen Jimenez, Grenoble (FR); Eirini Sarigiannidou, Saint Egreve (FR); Kader Zaidat, Saint Martin D''Heres (FR); Francois Weiss, Montbonnot (FR); Michel Pons, La Tronche (FR)

(73) Assignees: Institut Polytechnique De Grenoble, Grenoble (FR); Center National De La Recherche Scientifique, Paris Cedex 16 (FR)

(21) Appl. No.: 13/982,323

(22) PCT Filed: Jan. 30, 2012
(86) PCT No.: PCT/FR2012/050195

§ 371 Date: Jan. 9, 2014

(30) Foreign Application Priority Data
Jan. 31, 2011 (FR) 1150718

(51) Int. Cl. H01L 31/0368; H01L 31/068; H01L 31/18

(52) U.S. Cl. CPC H01L 31/03685; H01L 31/182; H01L 31/068

(57) ABSTRACT

The invention relates to a structure adapted for the formation of solar cells, comprising the following successive elements, namely: a sheet (1) of textured metal with crystal grains having an average size greater than 50 μm, said sheet being adapted to form a rear face electrode of the cells; a diffusion barrier layer (2) having a thickness of between 0.2 and 2 μm, made from an electrically conductive material with crystal grains having an average size greater than 50 μm; and a doped multicrystalline silicon layer (3) having a thickness of between 30 and 100 μm, with crystal grains having an average size greater than 50 to 100 μm, in which the average diffusion length of the carriers is greater than 50 μm.

### CROSS-REFERENCE TO RELATED APPLICATIONS

The present application is a National Stage of PCT International Application Ser. No. PCT/FR2012/050195, filed Jan. 30, 2012, which claims priority under 35 U.S.C. §119 of French Patent Application Ser. No. 11/50718, filed Jan. 31, 2011, the disclosures of which are incorporated by reference herein.

### BACKGROUND OF THE INVENTION

1. Field of the Invention

The present invention relates to a structure adapted to the forming of photovoltaic cells, currently called solar cells.

2. Description of the Related Art

Generally, the most commonly used solar cells are cells comprising a PN junction formed in silicon.

To manufacture solar cells, three types of substrate are generally used:

single-crystal silicon wafers;

To manufacture solar cells, three types of substrate are generally used:

single-crystal silicon wafers;

polysilicon wafers;

silicon deposits on various substrates.

The use of single-crystal silicon wafers provides the best efficiencies (maximum experimental efficiency 23%) but also results in extremely expensive products and such cells are practically only used when very high quality cells are necessary, for example, in satellites.

The use of polysilicon wafers results in a more advantageous compromise between the photoelectric cell output and the manufacturing cost, but requires using complex polysilicon ingot manufacturing installations. Above all, the different ingot conditioning operations (cropping, peeling) as well as the sawing of wafers result in a significant loss of material, of almost 50% of the ingot weight and of more than 50% of the initial silicon charge.

The deposition of a silicon layer on a conductive substrate, for example, metallic, is the less expensive solution but, in current techniques, this results in amorphous or microcrystallized silicon deposits. Now, a solar cell formed from amorphous silicon reaches an efficiency on the order of 5%, which is much lower than that of single-crystal silicon or polysilicon. In the case of microcrystallized silicon, the efficiency is in a higher range than that of amorphous silicon but is limited by a high defect rate with respect to crystal silicon. Such defects are generated by a high density of grain boundaries and by the accumulation of defects (dislocations, point defects, impurities . . . ) in the very grains.

Thus, current solar cell substrate manufacturing methods have various disadvantages in terms of compromise between cost and efficiency. Several approaches

1) Forming of crystal silicon at low temperature (T <630° C.) by physical vapor deposition techniques (ion-assisted cathode sputtering) on a substrate, such as disclosed in patent application US2006/0208257. This document essentially describes the forming of crystal silicon on an intermediate layer formed on an amorphous electrically-insulating support such as glass. Further, the forming of crystal silicon at temperatures lower than 800° C. provides a material having a high rate of structural defects, which adversely affects the conversion efficiency and limits the growth speed.

2) Deposition of crystallized silicon directly on a crystallographically-optimized metal substrate, such as described in patent applications EP2031082A1 and JP201018307. Such a solution has the advantage of transferring crystallographic characteristics to the silicon formed on the metal substrate. The reactivity at the interface between silicon and the substrate is not blocked, which limits silicon forming processes to techniques of chemical vapor deposition (CVD) at low temperature (T<600° C.). The formed material thus has the same disadvantages as that previously described, that is, a high rate of structural defects and a very low growth speed.

3) Silicon deposition on a metal support protected by an electrically-isolating barrier layer (silica, borosilicate, phosphosilicate), as described in patent U.S. Pat. No. 3,961,997. This enables to perform a polysilicon deposition at higher temperature, which results in a material of better crystalline quality and enables to reach larger deposited thicknesses. The reactivity between silicon and the substrate is treated by the forming of an electrically-isolating barrier layer. In such a method, the substrate can thus not play an active role in the photovoltaic cell and only forms a mechanical support for the deposited silicon.

4) Silicon deposition on a metal support protected by a bather layer of optically-transparent semiconductor or metallic material, as described in patent U.S. Pat. No. 4571448. The silicon layer is deposited by liquid deposition. A surface texturing of the support is performed to increase the reflection of light on the support.

Thus, prior art suggests silicon depositions on a metal support where:

either the silicon deposition is performed at a temperature lower than 800° C., whereby the silicon has a poor crystal quality;

or there exists an electrically-isolating or optically-transparent interface layer between the silicon and a metal support.

### SUMMARY OF THE INVENTION

An object of an embodiment of the present invention is to provide a structure comprising a crystal silicon layer on a metal sheet for the manufacturing of low-cost solar cells having a high photovoltaic conversion efficiency (>15%).

Another more specific object of the present invention is to provide such a structure for which the metal sheet can be used as an electrode for solar cells.

To achieve these and other objects, an embodiment of the present invention provides a structure adapted to the forming of solar cells, successively comprising a sheet of a textured metal with crystal grains having an average dimension greater than 50 μm, capable of forming a backside electrode of said cells; a diffusion bather layer having a thickness ranging from 0.2 to 2 μm made of a metallic electrically-conductive material selected from the group comprising TiN, TiAlN, TaN, CrN, and WSi₂, having crystal grains with an average dimension greater than 50 μm, the bather layer being formed in epitaxial relation with the sheet; and a doped multicrystal silicon layer of a thickness ranging from 30 to 100 μm, having crystal grains of average dimension greater than from 50 to 100 μm, wherein the carrier diffusion length has an average value greater than 50 μm, the multicrystal layer being formed in epitaxial relation with the barrier layer.

According to an embodiment of the present invention, the metal sheet is a sheet made of a material selected from the group comprising an iron-based metal alloy, a nickel-based metal alloy, a copper-based metal alloy, an austenitic steel, and a ferritic steel.

According to an embodiment of the present invention, the average crystal grain dimension in the metal sheet is greater than 1 mm.

An embodiment of the present invention provides a solar cell formed in the silicon layer of the above structure, wherein the metal sheet forms the backside electrode.

An embodiment of the present invention provides a method for manufacturing a structure such as hereabove, wherein the bather layer and the silicon layer are successively deposited by chemical deposition at temperatures ranging between 800 and 1,000° C.

### BRIEF DESCRIPTION OF THE DRAWINGS

FIG. 1 is a schematic view of the present invention.

The foregoing and other objects, features, and advantages will be discussed in detail in the following non-limiting description of specific embodiments in connection with the accompanying drawings, among which:

FIG. 1 shows an embodiment of a structure adapted to the forming of solar cells according to the present invention;

FIG. 2 is a partial simplified perspective view of an embodiment of a solar cell according to the present invention comprising the structure of FIG. 1; and

FIG. 3 is a partial simplified perspective view of another embodiment of a solar cell according to the present invention comprising the structure of FIG. 1.

For clarity, the same elements have been designated with the same reference numerals in the different drawings and, further, as usual in the representation of multilayer structures, the various drawings are not to scale.

### DESCRIPTION OF EMBODIMENTS OF THE PRESENT INVENTION

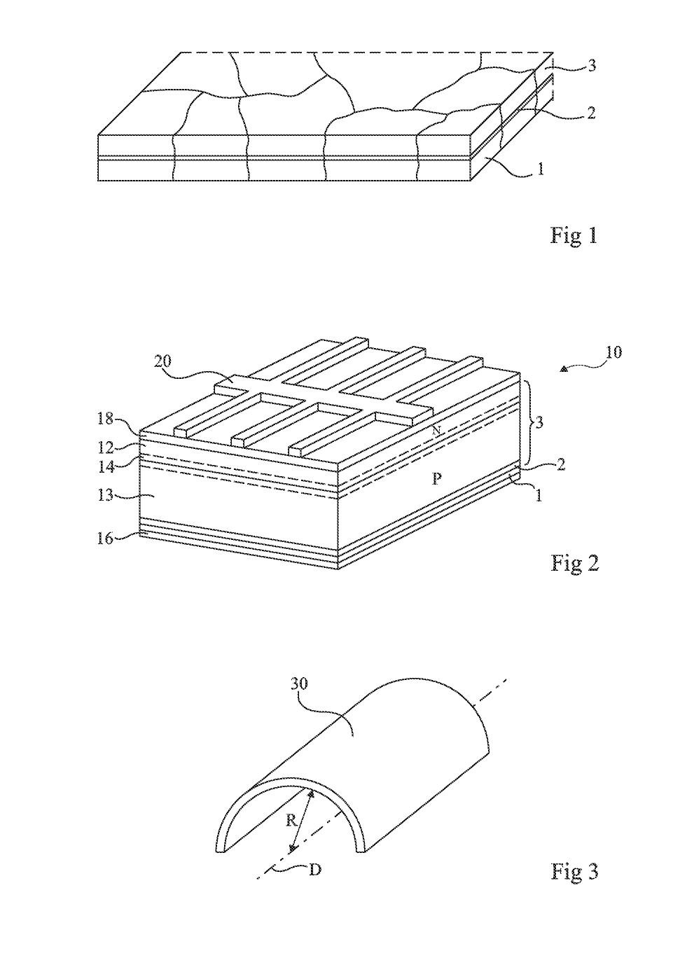

As illustrated in FIG. 1, a structure adapted to the forming of solar cells according to an embodiment of the present invention comprises, on a metal support 1, an electrically-conductive bather layer 2 and a multicrystal silicon layer, preferably doped as an electron acceptor (type P) 3.

Support 1 is a metal sheet having a sufficient thickness to ensure its mechanical hold, for example, a thickness greater than 100 μm. This sheet is formed from a structured metal, that is, a metal having crystal grains of relatively large dimension, for example, crystal grains having an average dimension greater than 50 μm, which may reach values ranging from 1 to 5 mm. An example of such a metal sheet is a stainless steel sheet, for example comprising a percentage of chromium approximately ranging from 15 to 25%. Such a product is commonly available for sale. The upper surface of this metal sheet is processed to be surface-deoxidized, for example, by a treatment with one or several acids such as hydrofluoric acid or nitric acid. Then, this upper surface is preferably polished to have an average roughness lower than 0.1 μm.

The bather layer is made of a material selected from the group comprising titanium nitride (TiN), titanium aluminum nitride (TiAlN), tantalum nitride (TaN), chromium nitride (CrN), and tungsten silicide (WSi2) or a mixture of these materials. There is a prejudice against the use of materials TiN, TiAlN, TaN, CrN, and WSi2 for forming of barrier layer 2. Indeed, these materials are known to be thermodynamically unstable in contact with silicon or in contact with steel (especially due to the presence of iron). It is especially known that in contact with silicon at high temperature, especially at a temperature greater than 800° C., materials TiN, TiAlN, TaN, CrN, and WSi2 tend to react with silicon to form new phases, which modifies and degrades the interface between the material and silicon. As an example, document “Interfacial reactions in Ti/Si3N4 and TiN-Si diffusion couples” by M. Paulasto, J. K. Kivilahti, and F. J. van Loo (Journal of Applied Physics volume 77, number 9, pages 4412-4416,1995) describes that in contact with silicon, titanium nitride reacts to form a new titanium suicide phase. The inventors have however shown that, unlike what used to be expected, materials TiN, TiAlN, TaN, CrN, and WSi₂ can be used to form bather layer 2. Indeed, the inventors have shown that, especially due to the conditions of manufacturing and use of the multilayer structure according to the invention, the kinetics of the reactions of these materials with silicon are sufficiently slow for the barrier layer material to remain substantially stable at least during the lifetime of products formed from the structure according to the invention.

The selection of a material selected from the group comprising TiN, TiAlN, TaN, CrN, and WSi₂ to form bather layer 2 enables to form a barrier layer 2 having advantageous properties.

Indeed, bather layer 2 substantially has a behavior similar to that of a metal. In particular, material TiN, TiAlN, TaN, CrN, and WSi₂ of bather layer 2 is a metallic electrically-conductive material (that is, the electric conduction is mainly ensured by free electrons and the electric resistivity of the material is strictly smaller than 1.10⁻⁵ ohm.m and preferably strictly smaller than 1.10⁻⁷ ohm.m), at least in a thin layer.

Further, barrier layer 2 forms an ohmic contact between sheet 1 and multicrystal silicon layer 3.

Further, barrier layer 2 reflects the light radiation crossing silicon layer 3 in a wide range of the solar spectrum, especially for wavelengths varying from 0.5 μm to 2 μm. For wavelengths greater than 2 μm, document “Optical properties of TiN films deposited by direct current reactive sputtering” by S. Adachi and M. Takahashi (Journal of Applied Physics volume 87, number 3, p. 1264) mentions a reflectance decrease by a factor greater than 2 for a TiN layer. In a structure where the barrier layer is made of a transparent or partially transparent material, photons must cross barrier layer 2 to reflect on metal sheet 1. Photons may thus be absorbed in bather layer 2, which decreases the photovoltaic efficiency of the solar cell formed from this multilayer structure.

Barrier layer 2 further has a good heat conductivity, that is, a heat conductivity greater than 10 W/(m.K). A temperature increase generally causes a decrease of the photovoltaic efficiency of a solar cell. The efficiency of a cell, determined from a standard procedure at ambient temperature (20° C.), decreases by a factor close to 0.1% per additional degree, this order of magnitude being provided by document “The effect of temperature on the power drop in crystalline silicon solar cells” by Radziemska (Renewable Energy, Vol. 28, number 1, pp. 1-12, January 2003). A cell exposed to sun, and especially if its support is thermally insulating, can see its temperature rise up to more than 60° C., which causes a significant efficiency decrease. For the solar cell to operate in an optimal range, it may be necessary to provide a system for cooling the solar cell. The good heat conductivity of bather layer 2 enables to limit the cell heating under lighting, or even to couple it with an efficient cooling system via metal sheet 1.

The material of barrier layer 2 is further selected to take, on deposition thereof, crystal characteristics substantially similar to those of the underlying support and to those of silicon. In particular, the material of barrier layer 2 enables to form bather layer 2 in epitaxial relation with sheet 1.

Materials TiN, TiAlN, TaN, CrN, and WSi₂ further have the advantage of not chemically reacting with the material of support 1.

Layer 2, which will be used as a bather layer to avoid the diffusion of silicon from the subsequently deposited layer to the metal and above all from the metal to this silicon layer, may have a thickness approximately ranging between 0.2 and 2 μm. Typically, this thickness may be on the order of 1 μm. This layer may be deposited by chemical vapor deposition, for example, from chlorinated compounds of titanium (TiCl₃) and aluminum (AlCl₃) in the presence of nitrogen or from metal-organic precursors such as tetrakis(dimethylamino)titanium (TDMAT or tetrakis(ethylmethylamido)titanium (TEMAT) in the presence of hydrogen or ammonia. The deposition may for example be performed at a low pressure, on the order of 10³ Pa, at a temperature approximately ranging from 800 to 1,000° C. An embodiment is described in document “LPCVD and PACVD (Ti,Al)N films: morphology and mechanical properties”, by S. Anderbouhr et al. (Surf. Coat Tech., 1999, 115, 2-3, 103-110). This layer may also be deposited by chemical liquid deposition or MOD, for MetalOrganic Decomposition. An example of the forming of TiN by this method is described in document “Formation of TiN by nitridation of TiO₂ films deposited by ultrasonically assisted sol-gel technique” by C. Jiménez and M. Langlet (Surface and Coatings Technology, 68-69:249-252, 1994).

Silicon layer 3 is formed by deposition on bather layer 2 in conditions enabling to at least partially keep the texture. In particular, the material of bather layer 2 enables to form silicon layer 3 in epitaxial relation with bather layer 2. The silicon, having a face centered cubic structure (fcc), is formed with a preferred orientation along axis <100> or <111> according to the growth conditions, to maximize the mesh parameter match with the material forming the barrier layer. This may be performed by conventional silicon CVD methods while however remaining below a 1,000° C. temperature and preferably between 800 and 900° C. to remain compatible with the presence of metal 1 which, as indicated, for example is steel. It can thus be observed that the texture of silicon layer 3 effectively is a multicrystal silicon texture having grains of the same order of magnitude as the grains of metal support 1. FIG. 1 shows a continuity of grain boundaries between metal support 1, bather layer 2, and multicrystal silicon layer 3. The crystallographic structure transfer provides final grain dimensions approximately ranging between 50 and 100 μm or more. Such features of the multicrystal silicon enable it to achieve, once used in a solar cell, photovoltaic conversion efficiencies greater than 15%. The provided deposition method enables to perform an in-situ doping, on deposition of the silicon layer, for example with boron.

The silicon layer is doped. An advantage of its forming by CVD at a temperature ranging between 800 and 1,000° C. is that the obtained grains have an excellent crystal quality, which is characterized by the fact that the carrier diffusion length in this layer reaches an average value greater than 50 μm.

Then, conventionally, solar cells may be formed in silicon layer 3 by forming of doped areas in the upper surface of this layer, and upper surface electrode deposition. Metal sheet 1 is then used as a backside electrode.

FIG. 2 schematically shows an embodiment of a solar cell 10. Solar cell 10 comprises a multilayer structure shown in FIG. 1 comprising metal sheet 1, bather layer 2, and multicrystal silicon layer 3. An N-type dopant implantation has been performed in multicrystal silicon layer 3 which is, as an example, initially P-type doped. Multicrystal silicon layer 3 then comprises an N-type doped region 12 covering a P-type doped region 13, region 13 being in contact with bather layer 2. A PN junction is thus present between P- and N-type doped regions 12, 13, which results in the forming of a depletion area 14 shown in FIG. 2 by dotted lines.

Solar cell 10 further comprises:

a protection layer 16 which covers metal sheet 1;

a transparent antireflection layer 18 which covers multicrystal silicon layer 3; and

a metal gate 20 at the surface of antireflection layer 18.

In operations, the light radiation causes the forming of electron/hole pairs in multicrystal silicon layer 3. The electrons are collected by metal gate 20.

The selection of the materials for forming sheet 1 and bather layer 2 and the thicknesses of sheet 1, of bather layer 2, and of silicon layer 3 give flexibility to the structure. The structure can thus be deformed without for this to cause a degradation of the properties of silicon layer 3. The solar cell according to the invention may be deformed to have a curved shape with, at least locally, a radius of curvature greater than or equal to 1 cm, preferably greater than or equal to 10 cm, and more preferably greater than or equal to 50 cm. The shape of the solar cell may be adapted according to the anticipated use of the solar cell. The structure according to the invention is thus adapted to the forming of a non-planar solar cell having a high photovoltaic conversion efficiency (>15%).

Further, protection layer 16 or one or several other layers covering protection layer 16 may have properties capable of giving the solar cell one or several additional functions in addition to the function of supplying an electric current. As an example, the solar cell may further be used as a structural element or a cladding element, for example, a panel, a slab, a tile, etc.

FIG. 3 shows an embodiment of a solar cell 30 having the shape of a half-cylinder of axis D and of radius R. In FIG. 3, the different layers forming the solar cell are not shown. As an example, radius R is greater than or equal to 1 cm, preferably greater than or equal to 10 cm, more preferably greater than or equal to 50 cm. Solar cell 30 is adapted to the forming of a tile.

The present invention is likely to have various alterations and modifications which will occur to those skilled in the art.

As concerns the material of the textured metal sheet, any conformable thin-sheet metallic material, having a crystal structure with a mesh parameter compatible with a growth of the barrier and crystal silicon layers, may be selected. One of the following materials may especially be selected: an iron-based metal alloy, a nickel-based metal alloy, a copper-based metal alloy, an austenitic steel, a ferritic steel.

The selection of a buffer layer such as mentioned hereabove enables to form by gas deposition at high temperature (T >800° C.), directly on an electrically-conductive substrate, a doped multicrystal silicon layer enabling to obtain high photovoltaic conversion efficiencies (>15%). Such an efficiency results from the forming of a silicon polycrystal having both a low density of grain boundaries and of structure defects, which results from the forming of the silicon layer at a temperature greater than 800° C. having a relation of epitaxy with the barrier layer which, itself, has a relation of epitaxy with the metal sheet. This layer may have a thickness ranging between 30 and 100 μm.

It should be noted that the metal sheet described herein has a triple function:

it is used as a mechanical support for the structure,

it transmits its crystallographic texturing to the overlying layers, and

it is intended to form the backside electrode of the cells formed from this structure.

1. A structure adapted to the forming of solar cells, successively comprising:
a sheet of a textured metal with crystal grains having an average dimension greater than 50 μm, capable of forming a backside electrode of said cells;
a diffusion barrier layer having a thickness ranging from 0.2 to 2 μm of a metallic electrically-conductive material selected from the group comprising TiN, TiAlN, TaN, CrN, and WSi₂, having crystal grains with an average dimension greater than 50 μm, the barrier being formed in epitaxial relation with the sheet; and
a doped multicrystal silicon layer of a thickness ranging from 30 to 100 μm, having crystal grains of average dimension greater than from 50 to 100 μm, wherein the carrier diffusion length has an average value greater than 50 μm, the multicrystal layer being formed in epitaxial relation with the barrier layer.

2. The structure of claim 1, wherein the metal sheet is a sheet made of a material selected from the group comprising an iron-based metal alloy, a nickel-based metal alloy, a copper-based metal alloy, an austenitic steel, and a ferritic steel.

3. The structure of claim 1, wherein the average dimension of the crystal grains in the metal sheet is greater than 1 mm.

4. The structure of claim 1, wherein the barrier layer is reflective.

5. A solar cell formed in the silicon layer of the structure of claim 1, wherein the metal sheet form the backside electrode.

6. The solar cell of claim 5, comprising at least one area having a radius of curvature greater than 1 cm.

7. A method for manufacturing the structure of claim 1, wherein the barrier layer and the silicon layer are successively deposited by chemical deposition at temperatures ranging between 800° and 1,000° C.

8. The structure of claim 2, wherein the average dimension of the crystal grains in the metal sheet is greater than 1 mm.

9. The structure of claim 2, wherein the barrier layer is reflective.

10. The structure of claim 3, wherein the barrier layer is reflective.

11. The method of claim 7 wherein a method for manufacturing the structure of claim 2, wherein the barrier layer and the silicon layer are successively deposited by chemical deposition at temperatures ranging between 800° and 1,000° C.

12. The method of claim 7 wherein a method for manufacturing the structure of claim 3, wherein the barrier layer and the silicon layer are successively deposited by chemical deposition at temperatures ranging between 800° and 1,000° C.

13. The method of claim 7 wherein a method for manufacturing the structure of claim 4, wherein the barrier layer and the silicon layer are successively deposited by chemical deposition at temperatures ranging between 800° and 1,000° C.

14. A solar cell of claim 5 wherein the metal sheet is a sheet made of a material selected from the group comprising an iron-based metal alloy, a nickel-based metal alloy, a copper-based metal alloy, an austenitic steel, and a ferritic steel.

15. A solar cell of claim 5 wherein the average dimension of the crystal grains in the metal sheet is greater than 1 mm.

16. A solar cell of claim 5 wherein the barrier layer is reflective.

17. A solar cell of claim 6 wherein the metal sheet is a sheet made of a material selected from the group comprising an iron-based metal alloy, a nickel-based metal alloy, a copper-based metal alloy, an austenitic steel, and a ferritic steel

18. A solar cell of claim 6 wherein the average dimension of the crystal grains in the metal sheet is greater than 1 mm.

19. A solar cell of claim 6 wherein the barrier layer is reflective.

20. A solar cell of claim 14 wherein the average dimension of the crystal grains in the metal sheet is greater than 1 mm.
